(19) United States
(12) Patent Application Publication
(10) Pub. No.: US 2010/0145640 A1
(43) Pub. Date: Jun. 10, 2010

(54) SYSTEM AND METHOD FOR ELECTRICAL PARAMETER ESTIMATION

(76) Inventors: Esau Aguinaga, Chihuahua (MX); Norberto Hernandez, Chihuahua (MX); Jesus Carmona, Columbus, IN (US)

Correspondence Address: DELPHI TECHNOLOGIES, INC;LEGAL STAFF - M/C 483-400-402, 5725 DELPHI DRIVE, PO BOX 5052, TROY, MI, 48007, US

(21) Appl. No.: 12/331,748

(22) Filed: Dec. 10, 2008

(51) Int. Cl. G01R 27/26

(52) U.S. Cl. 702/57

(57) ABSTRACT

A method is provided for estimating an electrical parameter of a circuit-under-test (e.g., resistance, capacitance and/or inductance). The method acquires samples during a plurality of charging cycles rather than during just one, which allows an extended overall time period to acquire such samples. The first step involves defining a major sampling period having a plurality of minor sampling periods. A number of steps are performed for each minor sampling period: applying an excitation signal to the circuit-under-test to produce a respective induced, response signal and acquiring a respective sample of the induced signal at a respective predetermined deferral time. In an embodiment where the circuit-under-test includes an unknown capacitance, the excitation signal may be a unit step while an increase in the induced signal is governed by a charging time constant, which itself is indicative of the unknown capacitive. The electrical parameter may be determined based on the acquired samples, which collectively constitute a composite response. The composite response is processed, for example, by fitting it to a normalized capacitive charging curve, to ascertain an estimate of the unknown capacitive.

### TECHNICAL FIELD

The present invention relates generally to sensing and estimation systems and, more particularly, to a system and method for electrical parameter estimation.

### BACKGROUND OF THE INVENTION

Sensing a parameter of interest is an important task in any automatic and/or monitoring system. Moreover, digital sensors have very convenient features that allow for very complex processing capabilities. However, the tradeoff for convenience and features is cost.

Sensing is typically made by some measurement that can be translated to a variable of interest. Often times there are off-the-shelf transducers (or chips) configured to provide a voltage as their output which can be provided to an analog-to-digital (A/D) converter for further processing and/or transmission. Some chips even provide a digital stream of bits with the variable of interest encoded therein. It is also conventional to use a processing unit (PU) or the like to either (1) perform the A/D conversion via a built-in A/D and converter and/or (2) to handle/process the incoming bit stream.

While it is known to use a processing unit (e.g., microcontroller) with an A/D converter function to measure some electrical parameter of interest (e.g., resistance, capacitance, inductance), there is often a tradeoff between cost and performance. In other words, while a conventionally configured, low-cost microcontroller may be adequate where sampling throughput requirements are not very high, for high sampling rate situations they are typically not viable options. It would thus be desirable to be able to utilize a low-cost microcontroller to achieve, in effect, high sampling rate performance.

There is therefore a need for a system and method that minimizes or eliminates one or more of the problems set forth above.

### SUMMARY OF THE INVENTION

The invention provides a system and method to achieve a high effective sampling rate using a low-cost microcontroller or the like. Embodiments of the invention may be used, for example, for dynamic electrical parameter estimation (e.g., for estimation of resistance, capacitance and/or inductance of a circuit).

A method is provided for estimating an electrical parameter of a circuit-under-test. In concept, the invention calls for acquiring multiple samples from multiple charging cycles, rather than acquiring multiple samples from just one charging cycle as is conventional. The timing of the sampling within each charging cycle is adjusted and controlled so that representative samples are taken at various time constants, albeit occurring in different charging cycles. This approach allows for the use of a low-cost, low throughput microcontroller, since there is no need to have a high throughput device capable of taking all the samples during one charging cycle.

The method includes a number of steps. The first step involves defining a major sampling period having a plurality of minor sampling periods. The next step involves, for each minor sampling period: (i) resetting or otherwise assuring that the circuit-under test is in a known state (e.g., is discharged); (ii) applying an excitation signal to the circuit-under-test to thereby produce a respective induced, response signal; and (iii) acquiring a respective sample of the induced signal at a respective, predetermined deferral time. In an embodiment where the circuit-under-test includes an unknown capacitance to be estimated, the resetting step includes the sub-step of discharging the circuit-under-test or ensuring that it is discharged. In such an embodiment, the excitation signal may be a unit step while the induced signal increases in accordance with a charging time constant indicative of the unknown capacitive. The final step involves determining the electrical parameter (e.g., capacitance) based on the acquired samples.

In a preferred embodiment, the samples, in the collective, define a composite response. The composite response is processed, for example, by fitting it to a normalized capacitive charging curve, to ascertain an estimate of the capacitive (i.e., the electrical parameter).

A system is also presented.

### BRIEF DESCRIPTION OF THE DRAWINGS

The present invention will now be described by way of example, with reference to the accompanying drawings:

FIG. 1 is a schematic and block diagram showing an environment in which the invention may be practiced.

FIG. 2 is voltage versus time diagram showing, in normalized fashion, a capacitor charging characteristic.

FIG. 3 is a flowchart showing a method in accordance with the invention for estimating an electrical parameter of a circuit-under-test.

FIG. 4 is a voltage versus time diagram showing a major sampling period subdivided into a plurality of minor sampling periods.

FIG. 5 is a simplified schematic and block diagram showing a conventional input to an analog-to-digital (A/D) converter.

FIG. 6 is a voltage versus time diagram showing data obtained using an embodiment of the invention.

### DETAILED DESCRIPTION OF THE PREFERRED EMBODIMENT

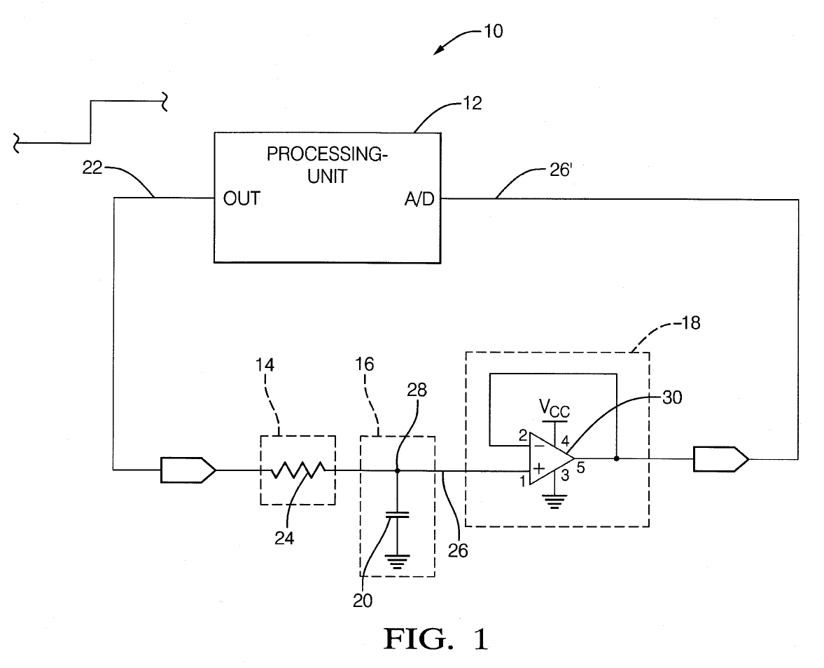

Referring now to the drawings wherein like reference numerals are used to identify identical components in the various views, FIG. 1 is a simplified schematic and block diagram of a system 10 configured for dynamic electrical parameter estimation. The system 10 includes a processing unit (PU) 12, an optional first interface 14, a circuit-under-test 16 and an optional second interface 18. The circuit-under-test 16 may be characterized by one or more electrical parameters which may be of interest and which may need to be estimated, such as resistance, capacitance and/or inductance. For purposes of description, the electrical parameter of interest for the circuit-under-test 16 is capacitance. This is represented as a capacitor 20 having an unknown capacitance value, herein designated Cx. A well known approach for determining the value of an unknown capacitance is to charge the capacitance through a known resistance, and to then measure the voltage levels throughout the single charging cycle at various points in time. From these voltage level samples, one can determine a charging time constant, and if the resistance is known, the capacitance value can be calculated.

In this regard, for purposes of charging the circuit-under-test 16, the PU 12 is configured to produce an excitation signal 20 on an output terminal thereof. The excitation signal 20 may be a unit step function signal. Of course, other signals are possible depending on the nature of the circuit-under-test 16. In addition, in the case where the electrical parameter of interest is capacitance, the first interface 14 includes a charging resistor, such as a resistor 24, having known resistance R Ω. In general, when the excitation signal 22 is applied to the circuit-under-test 16, an induced voltage signal 26 is produced on an electrical node 28. The induced signal 26 may be sampled by an analog-to-digital (A/D) converter included in the PU 12, as shown in FIG. 1. This may be done directly. Alternatively, however, and as shown, the induced signal 26 may be applied through the optional second interface 18 to produce an induced signal 26′, which is then sampled by the A/D of the PU 12. In one embodiment, the interface 18 includes an operational amplifier 30 configured to present a relatively low output impedance for improved performance, as described in greater detail below.

The PU 12 may be a conventional microcontroller, including at least one microprocessor or other processing unit, associated memory devices such as read only memory (ROM) and random access memory (RAM), a timing clock, one or more inputs for monitoring input from external analog and digital devices and one or more outputs for controlling output devices. As described above, in the illustrative embodiment, the PU 12 includes at least one output configured to generate the excitation signal 20. The PU 12 also includes at least one input, such as an analog-to-digital (A/D) converter input, for acquiring samples of the induced signal 26 (or 26′) at predetermined times under the control of a control program or the like executing in the PU 12. The sampled signal 26 (or 26′) converted by the A/D results in a digital word having a predetermined number of bits, as known. The digital words are stored for further processing, as described below. The PU 12 can be of the low-cost variety, having reduced throughputs (e.g., 30-70 k Samples Per Second (SPS)).

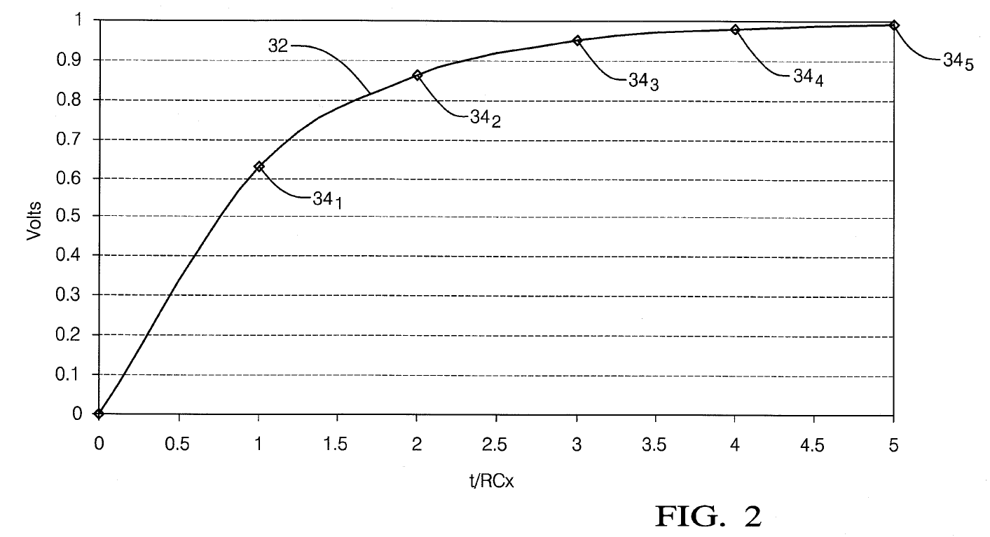

FIG. 2 is voltage versus time diagram showing, in normalized fashion, a capacitor charging curve 32. When the excitation signal 22, which may be a unit step, is applied to the circuit-under-test 16 through the charging resistor 24, the induced response signal 26 will take the form of the curve 32. The X-axis in FIG. 2 is normalized and denotes any combination of resistance values (R) and capacitance values (Cx) (i.e., the X-axis is expressed in units of time constants—t/RCx). One approach to determine the value of the unknown capacitance is to fit the acquired data (e.g., using a least squares fit) to the data expressed in graph form in FIG. 2. For example, a plurality of points 34₁, 34₂, 34₃, 34₄ and 34₅ taken from curve 32 correspond to samples for each integer increment of the RCx time-constant. This data may be stored in a chart or table for use during execution. For instance, if a 5V unit step is applied to the RCx network, the capacitor voltage at any given time ‘t’ would be Vo=5 (1−exp (−t/RCx)). From this equation, one can obtain Cx since R, t and Vo are known: Cx=−t/(R (In (1−(Vo/5)))). This equation can be used for any single sample obtained. For a more accurate measurement, a set of estimations given by the last equation can be averaged.

As described in the Background, one issue involves price/performance tradeoffs for the PU 12. If, as a rule of thumb to accurately estimate capacitance, one wishes to take one sample at least every time constant, the sampling period (T) would be defined as the product of (R)(Cx). For example, for a resistance value of R=1 MΩ and a capacitance value of Cx=1 pF, the sampling period would be T=(1E6)(1E−12)=(1E−6)=1 μs, or in other words, a requirement of 1 million samples per second. Low-cost microcontrollers presently can only usually reach about 30-70 kSPS (thousands of Samples Per Second). Accordingly, achieving such sampling rates using conventional approaches would rule out the use of conventional low-cost microcontrollers, which would be throughput-limited using conventional sampling approaches. The invention, however, provides a solution enabling even such low-cost microcontrollers to effectively achieve elevated performance levels.

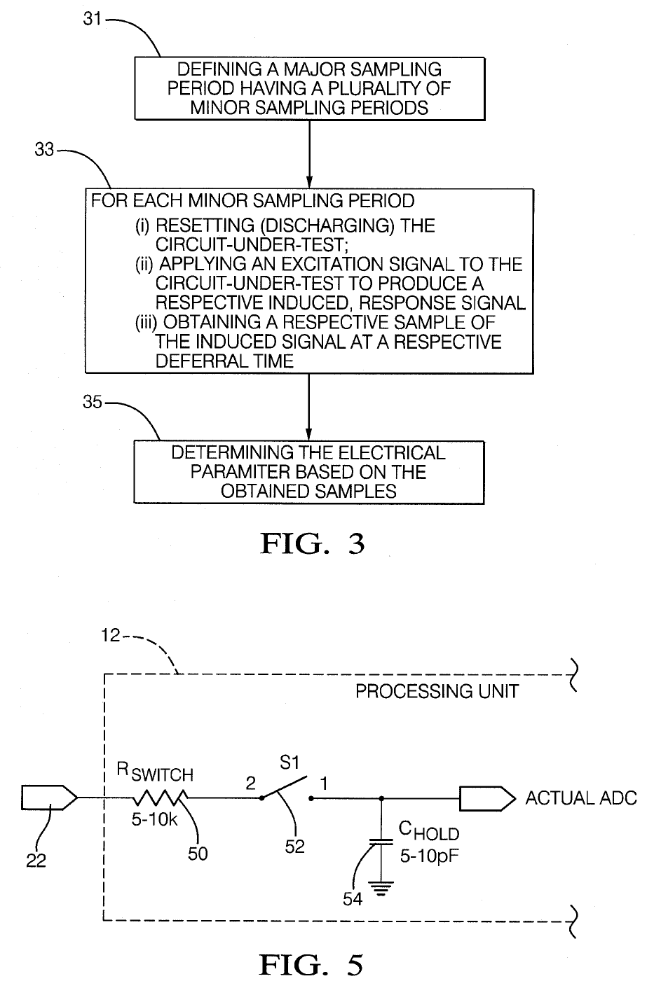

FIG. 3 is a flowchart diagram describing a method of the invention which solves these and other problems. Generally, the invention solves these problems by establishing a separate charging cycle for each sample that is to be acquired, rather than trying to acquire all the samples on a single charging cycle using a throughput-limited device. Low-cost microcontrollers are generally not fast enough to acquire all the samples needed for parameter estimation during a single charging cycle, particularly for very short time-constant circuits-under-test. For each charging cycle (also referred to as the “minor sampling period”), the excitation signal 22 is applied and the sample is acquired in such a way that it is acquired at the same point in its individual charging cycle as it would have been had all the samples been taken off the same charging cycle. The samples are then considered together to form a composite response to the excitation signal 22. The method for implementing this approach begins in step 31.

In step 31, the method involves defining a major sampling period that is subdivided into a plurality of minor sampling periods. The major sampling period defines the overall period of time in which samples are being taken to form the composite response, which is in turn used to determine a value for an electrical parameter of interest. The minor sampling periods define independent charging cycles for which at least one sample of the induced signal can be acquired. The minor sampling periods may be selected to be long enough to acquire a sample over at least two time-constants. In the illustrated embodiment, the minor sampling periods are at least five time-constants long. The individual samples are then added to the set of samples that collectively define the composite response. The method proceeds to step 33.

In step 33, the method involves performing, for each minor sampling period: (i) resetting, discharging or otherwise ensuring that the circuit-under-test 16 is in a known state (e.g., discharged); (ii) applying the excitation signal 22 to the circuit-under-test 16 to thereby charge, in the case of a capacitor, the circuit-under-test 16 and thus produce a respective induced, response signal 26; and (iii) acquiring a respective sample of the induced signal 26 at a respective predetermined deferral time. Thus, each minor sampling period defines its own independent charging cycle for the purpose of acquiring a sample at the predetermined, deferral time. Also, as alluded to, the respective deferral times are each selected so that, in the aggregate, the set of acquired samples fairly characterizes the charging response, and meets predetermined sampling criteria as if all the samples had been taken from one charging cycle. In one embodiment, the deferral times are selected so that at least one sample is taken for each time constant. The method proceeds to step 35.

In step 35, the method involves determining the electrical parameter based on the plurality of acquired samples. In effect, the plurality of samples are taken together to define a composite response produced by the applied excitation signal 22.

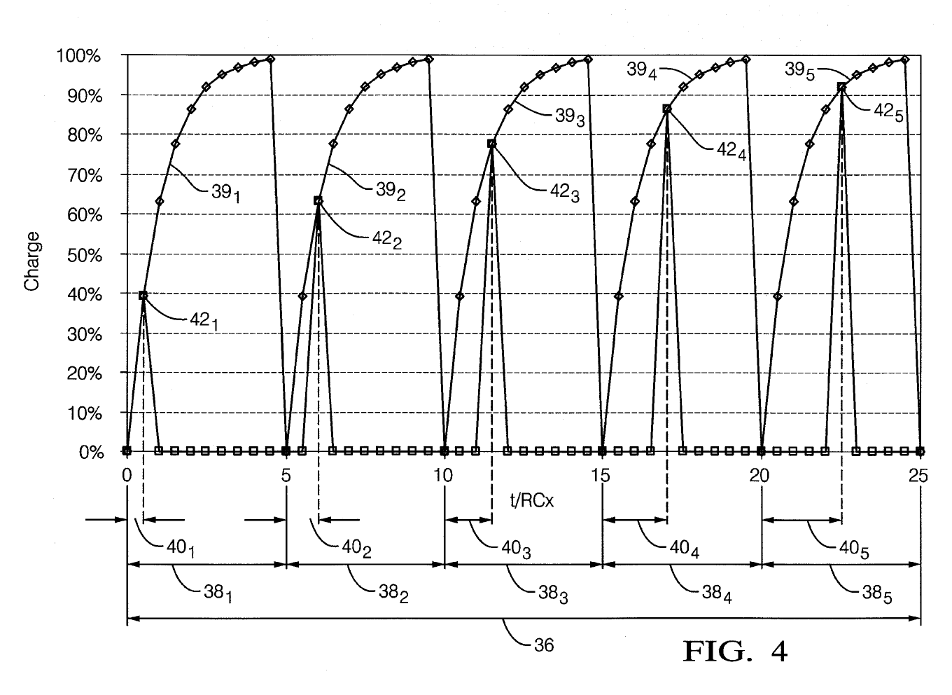

FIG. 4 is a voltage (charge) versus time diagram showing operation of the dynamic electrical parameter estimation to illustrate the invention. The entire time period during which samples are acquired by the PU 12 may be defined as the major sampling period 36, which in turn is subdivided into a plurality of minor sampling periods (or charging cycles), such as minor sampling periods 38₁, 38₂, 38₃, 38₄ and 38₅. In the illustrative embodiment, the minor sampling periods are equal, although this is not per se required. At the beginning of each minor sampling period 38ᵢ, the circuit-under-test 16, specifically the capacitance thereof, is assumed to be discharged. This may be due to natural discharge to ground, or may be controlled directly by the PU 12 by, for example, bringing the terminal on which the excitation signal is generated directly to ground so as to provide a discharge path. Other approaches are possible and remain within the spirit and scope of the invention. The main point is that the circuit-under-test 16 is in a known, preferably discharged state. For each of the minor sampling periods 38₁, 38₂, 38₃, 38₄ and 38₅, the excitation signal 22 (e.g., unit step) is applied to commence the charging cycle of the combination of the resistor 24 (R) and the circuit-under-test 16 (Cx). The trajectory of the voltage due to the charge build-up on capacitor 20 is shown at 39₁ for the minor sampling period 38₁, shown at 39₂ for the minor sampling period 38₂, shown at 39₃ for the minor sampling period 38₃, and so on.

Each minor sampling period 38ᵢ has a respective predetermined deferral time associated therewith. For the exemplary five minor sampling periods 38₁, 38₂, 38₃, 38₄ and 38₅ as shown, there are five corresponding predetermined deferral times designated 40₁, 40₂, 40₃, 40₄ and 40₅, respectively, each measured or taken with respect to the beginning of its minor sampling period. The processing unit 12 is configured to delay the start of the A/D converter in acquiring samples by these amounts of time. As shown in FIG. 4, a plurality of samples 42₁, 42₂, 42₃, 42₄ and 42₅ are acquired at respective deferral times of 0.5, 1.0, 1.5, 2.0 and 2.5 (i.e., each tick mark in FIG. 4 is equal to 0.5). For each sample, the capacitor 20 of the circuit-under-test 16 is first charged and once the sample is taken, the capacitor is discharged or allowed to discharge for the next-succeeding minor sampling period (charging cycle). A curve can be traced through the acquired samples 42₁, 42₂, 42₃, 42₄ and 42₅ so that the samples define, collectively, a composite response to the excitation signal (unit step).

FIG. 5 is a simplified schematic and block diagram showing a typical input interface to an analog-to-digital (A/D) converter that would be internal to a conventional processing unit. On-chip A/D converters (i.e., internal to the microcontroller itself) are typically connected through an interface to an external pin or terminal for receiving the analog voltage to be converted. This interface may include a resistor 50 (having a resistance value Rswitch, typically 5-10 k Ω), a switch 52 (S1) and a capacitor 54 (having a capacitance value Chold, typically 5-10 pF). The resistance and the capacitance components present a load, which has the effect of deforming the acquired data (e.g., as shown above, FIG. 2). In another aspect of the invention, however, the second interface 18 includes the operational amplifier 30 configured in a unity gain follower arrangement. The operational amplifier 30 exhibits a reduced output impedance, as compared to the resistor 24 (R) and capacitor 20 (Cx) network, thereby minimizing distortion when its output is sampled by the A/D.

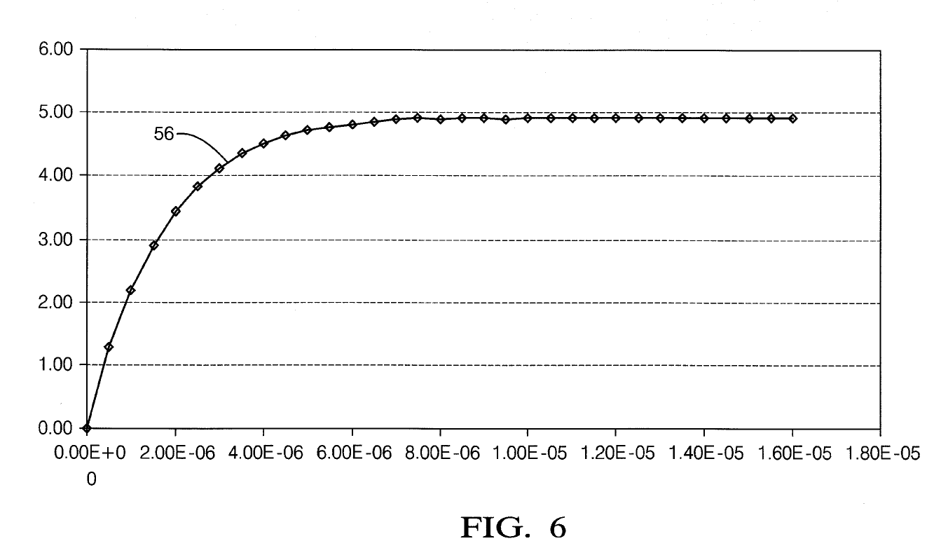

FIG. 6 is a voltage versus time diagram showing data obtained through the use of an embodiment of the invention. In particular, FIG. 6 shows data obtained in an embodiment where R=121 kΩ and Cx=12 pF. In this embodiment, the maximum sampling period is calculated as follows: R*Cx=1.45 μs. It should be appreciated that in FIG. 6, a 0.5 μs “sampling period”, in effect, was achieved. The sampling rate is only limited by the timing of a machine cycle of the PU 12.

Many variations of embodiments of the invention are possible. For example, when estimating capacitance, the RC network under test can be fully charged to an initial value, and the above-described samples can be acquired while allowing the circuit-under-test to discharge. Also, for example, if highly accurate capacitance measurements (or a very stable sampling period) are required, a ceramic resonator can be added to the system 10 to enforce greater precision in the timing of the various minor sampling periods, the deferral times, and the like. It should be understood that variation in the timing of acquiring a sample can result in sampling a higher or lower voltage than intended, and result in variation in the calculation of Cx. Another source of accuracy is the relative precision of the value of resistor 24 (R) (i.e., variation in R would likewise affect the calculation of Cx). On the other hand, if only relative (rather than absolute) capacitance measurements are required, then a ceramic/crystal resonator might not be required. In addition, while five minor sampling periods are shown in an illustrative embodiment, the invention contemplates that greater or fewer than five minor sampling periods may be appropriate under various circumstances (e.g., 2, 3, 4 or 6, 7 or higher).

The invention provides an affordable configuration for dynamic estimation of an electrical parameter, so long as output refresh rates do not exceed the capability of the processing used in any constructed embodiment. While the illustrative embodiment involved estimation of a capacitance value, it should be understood that the invention is not so limited, and may be extended to and applied to any electrical network including, alone or in combination, a resistance, capacitance and/or an inductance.

It should be understood that the processing unit (PU) 12 as described above may include conventional processing apparatus known in the art, capable of executing pre-programmed instructions stored in an associated memory, all performing in accordance with the functionality described herein. That is, it is contemplated that the processes described herein will be programmed in a preferred embodiment, with the resulting software code being stored in the associated memory. Implementation of the invention, in software, in view of the foregoing enabling description, would require no more than routine application of programming skills by one of ordinary skill in the art. Such a processing unit may further be of the type having both ROM, RAM, a combination of non-volatile and volatile (modifiable) memory so that the software can be stored and yet allow storage and processing of dynamically produced data and/or signals.

While particular embodiments of the invention have been shown and described, numerous variations and alternate embodiments will occur to those skilled in the art. Accordingly, it is intended that the invention be limited only in terms of the appended claims.

1. A method of estimating an electrical parameter of a circuit-under-test, comprising the steps of:
defining a major sampling period having a plurality of minor sampling periods;
for each minor sampling period
(i) resetting the circuit-under test to a known state;
(ii) applying an excitation signal to the circuit-under-test to thereby produce a respective induced, response signal;
(iii) acquiring a respective sample of the induced signal at a respective predetermined deferral time; and
determining the electrical parameter based on the samples.

2. The method of claim 1 further including the step of:
providing a first interface through which the excitation signal is applied to the circuit-under-test.

3. The method of claim 2 wherein the electrical parameter is a capacitance value (Cx), said step of providing the first interface includes the sub-step of:
selecting a charging resistance value (R) for the first interface.

4. The method of claim 3 wherein said step of providing the first interface includes the sub-step of:
arranging the first interface in series with the circuit-under-test.

5. The method of claim 1 further including the step of:
providing a second interface through which the induced signal is sampled.

6. The method of claim 5 wherein said induced signal is a voltage on a first node, said step of providing the second interface includes the sub-step of:
providing a unity gain buffer amplifier having an input thereof connected to the first electrical node and wherein said samples are obtained from an output of said amplifier, said amplifier having a desired output impedance.

7. The method of claim 6 wherein said induced signal is an analog signal, said step of acquiring said samples includes the sub-step of converting the induced signal at the respective deferral times into corresponding digital words.

8. The method of claim 1 wherein said resetting step includes the sub-step of discharging the circuit-under-test.

9. The method of claim 1 wherein each predetermined deferral time is measured from the beginning of a respective minor sampling period.

10. The method of claim 1 wherein said samples are concatenated to form a composite response to the excitation signal.

11. The method of claim 10 wherein said step of determining the electrical parameter further includes the sub-step of using the composite response.

12. The method of claim 11 wherein said step of determining the electrical parameter includes the sub-step of:
determining a least squares fit of the composite response to predetermined data.
